(19) United States
(12) Patent Application Publication
(10) Pub. No.: US 2026/0123459 A1
(43) Pub. Date: Apr. 30, 2026

(54) INTEGRATED CIRCUIT PACKAGE HAVING A LEADED SUBSTRATE

(71) Applicant: TEXAS INSTRUMENTS INCORPORATED, DALLAS, TX (US)

(72) Inventors: FRANCIS GLYDE MEDINA, LA UNION (PH); JOVENIC R. ESQUEJO, BAGUIO CITY (PH); VON MARK MENDOZA, BAGUIO CITY (PH)

(21) Appl. No.: 18/930,641

(22) Filed: Oct. 29, 2024

(51) Int. Cl. H01L 23/498; H01L 21/48; H01L 21/56; H01L 23/00; H01L 23/31

(52) U.S. Cl. CPC H10W 70/479; H10W 70/093; H10W 70/095; H10W 70/65; H10W 74/016; H10W 74/117; H10W 90/701; H10W 90/724

(57) ABSTRACT

An electronic device includes a leadframe and a substrate assembly. The substrate assembly includes a leadframe attachment feature configured to attach to the leadframe. At least one metal layer is embedded in the substrate assembly, where the at least one metal layer has an exposed surface. A die is attached to the exposed surface of the at least one metal layer and a mold compound encapsulates the substrate assembly and the die.

### TECHNICAL FIELD

The present disclosure relates to electronic devices, and more specifically to electronic devices having a leaded substrate-based package.

### BACKGROUND

Wire bonding is an integrated circuit (IC) manufacturing method used in more than 40 billion microelectronic devices each year. Wire bonding is used extensively for interconnecting semiconductor chips to package leads and many other applications that allow the microelectronic devices to meet stringent size, weight, power, and cost requirements. Wire bonding, however, does present certain challenges and risks. For example, IC packages that include wire bonds for electrically attaching a die to leads on a leadframe, have limited capabilities relating to circuit complexity. In other words, the wire bonded packages are limited as to how circuits are laid out in the package. Other typical failure examples include bond pad adherence and peeling of the pads. In addition, the wire bonds can be positioned poorly, resulting in failures at the bonding points.

### SUMMARY

In a described example, an electronic device includes a leadframe and a substrate assembly having a leadframe attachment feature configured to attach to the leadframe. At least one metal layer is embedded in the substrate assembly, where the at least one metal layer has an exposed surface. A die is attached to the exposed surface of the at least one metal layer and a mold compound encapsulates the substrate assembly and the die.

In another described example, an electronic device includes a substrate having a first surface and a second surface. A first metal layer is deposited on the first surface of the substrate and a second metal layer deposited on the second surface of the substrate. A resist material layer is disposed on the first and second surfaces of the substrate and over the first and second metal layers. The resist material includes openings to expose portions of the first metal layer. A leadframe is attached to a leadframe attachment feature disposed on the substrate. A die is attached to the first metal layer and a mold compound is formed over the substrate and the die.

In still another described example, a method includes forming at least one metal layer on at least one surface of a substrate and forming contact pads on the at least one surface of the substrate. The contact pads of the substrate are attached to a leadframe via first interconnects. A die is attached to the at least one metal layer via second interconnects and a mold compound is formed over the substrate and the die.

### BRIEF DESCRIPTION OF THE DRAWINGS

FIG. 1 is a cross-sectional view of an example electronic device.

FIGS. 2A and 2B are top and bottom views respectively of an example substrate.

FIG. 2C is a top view of an example leadframe.

FIG. 2D is a transparent top view of the substrate of FIGS. 2A and 2B.

FIG. 3 is a block diagram flow chart explaining a fabrication process of the electronic device of FIG. 1.

FIG. 4A illustrates a cross-sectional view of a substrate in the early stages of fabrication.

FIG. 4B illustrates a cross-sectional view of the substrate of FIG. 4A after undergoing a laser drilling/etching process.

FIG. 4C illustrates a cross-sectional view of the substrate of FIG. 4B after undergoing a photoresist material layer patterning.

FIG. 4D illustrates a cross-sectional view of the substrate of FIG. 4C after undergoing a plating process.

FIG. 4E illustrates a cross-sectional view of the substrate of FIG. 4D after undergoing removal of the photoresist material layer.

FIG. 4F illustrates a cross-sectional vies of the substrate of FIG. 4E after undergoing an etching process.

FIG. 4G illustrates a cross-sectional view of the substrate of FIG. 4F after under going a lamination process.

FIG. 4H illustrates a cross-sectional view of the substrate of FIG. 4G after undergoing deposition of a protective layer.

FIG. 4I illustrates a cross-sectional view of the substrate of FIG. 4H after undergoing deposition of interconnects on contact pads of the substrate.

FIG. 4J illustrates a cross-sectional view of the substrate of FIG. 4I after rotation of the substrate by 180° and attaching the substrate to a leadframe.

FIG. 4K illustrates a cross-sectional view of the substrate of FIG. 4J after rotation of the substrate and leadframe by 180°.

FIG. 4L illustrates a cross-sectional view of the substrate of FIG. 4K after placement of a die on the substrate.

FIG. 4M illustrates a cross-sectional view of the substrate of FIG. 4L after undergoing a formation of a mold compound.

FIG. 4N illustrates a cross-sectional view of the substrate of FIG. 4M after forming and shaping external leads of the leadframe to form the electronic device of FIG. 1.

### DETAILED DESCRIPTION

Electronic device (e.g., integrated circuit (IC)) packages such as a quad-flat package (QFP) or a quad-flat no-lead package (QFN) utilize wire bonds to connect electrically a die to the leads of the package for power and signal transmission. The wire bonds, however, present certain challenges and risks. For example, IC packages that include wire bonds have limited capabilities relating to circuit complexity. In other words, the wire bonded packages are limited as to how circuits are laid out in the package. Other typical failure examples include bond pad adherence and peeling of the pads. In addition, the wire bonds can be positioned poorly, resulting in failures at the bonding points.

Disclosed herein is an electronic device and process of making that includes a leaded substrate to replace the wire bonds that overcomes the aforementioned disadvantages. The leaded substrate configuration combines an external leadframe with an internal substrate (re-distribution layer (RDL)). Solder paste or solder balls provide a connection between the substrate and internal leads of the leadframe. The leaded substrate acts as a re-distribution layer (RDL) that simplifies complex wire bond configurations that attach a die to the leadframe by rerouting circuits through the substrate. In addition, the leaded substrate configuration facilitates the use of high pin count dies in small leaded packages.

Still further, flip chip dies can replace existing wire bonded leaded packages thereby eliminating wire bond issues described above. Flip chip dies provide several advantages over wire bonding packages. For example, flip chip connections (e.g., conductive material such as solder) provide improved electrical and thermal performance due to the shorter interconnection paths and reduced inductance. Flip chip connections provide higher interconnect density on the substrate, as it eliminates the need for wire bonding and allows more connections in a given area. In addition, the connections made using flip chip dies have improved mechanical strength, making them more reliable in various operating conditions. Still further, the direct flip chip connections facilitate better heat dissipation, which is crucial in many semiconductor applications. Finally, the leaded substrate configuration enables the use of a single sized leadframe (e.g., n×n) that can be used with different sized substrates to create multiple semiconductor packages based on the application.

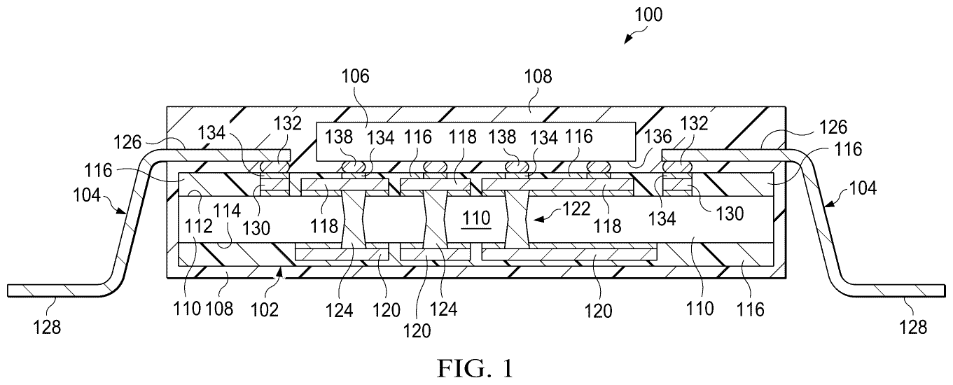

FIG. 1 is a cross-sectional view of an example electronic device (e.g., integrated circuit (IC)) 100. The example electronic device 100 described herein and illustrated in the figures is a leaded substrate type device, but can be comprised of any type of leaded integrated circuit (IC) including, but not limited to a quad-flat package (QFP), quad-flat no-lead (QFN), etc. Thus, the example electronic device 100 illustrated in FIG. 1 is for illustrative purposes only and is not intended to limit the scope of the invention. The electronic device 100 includes a substrate assembly 102 attached to a leadframe 104, a die 106 attached to the substrate assembly 102, and a mold compound 108.

The substrate assembly 102 is comprised of a substrate 110 (e.g., Epoxy, Ajinomoto Build-up Film (ABF), or Bismaleimide Triazine (BT)) that has a first surface 112 and a second surface 114 and a resist material layer 116 disposed on both the first and second surfaces 112, 114 of the substrate 110. Multiple metal layers (traces) are embedded in the substrate assembly 102. The number of metal layers embedded in the substrate assembly 102 can be any number ranging from 2 to N, where N is the maximum number for a given electronic device 100. For simplicity, the example electronic device 100 described herein and illustrated in FIG. 1 includes two metal layers comprising a first metal layer 118 and a second metal layer 120.

A via layer 122 comprised of multiple vias 124 is disposed between the first metal layer 118 and the second metal layer 120. In other example electronic device packages, however, another via layer 122 may be disposed between the second metal layer 120 and a third metal layer, and still another via layer 122 may be disposed between the third metal layer and a fourth metal layer, etc. The via layer 122 provides an electrical connection between the first metal layer 118 and the second metal layer 120. Depending on the application and the package design, the vias 124 may be cylindrical, hollow vias with plated copper walls or solid copper vias or a combination of the two. The vias 124 facilitate the electrical connection between the first metal layer 118 and the second metal layer 120 and assist in the thermal performance of the electronic device 100.

The leadframe 104 is comprised of internal (inner) leads 126 disposed inside the mold compound 108 and external (outer) leads 128 disposed outside the mold compound 108. The external leads 128 extend from the internal leads 126 away from the mold compound 108 and are configured to attach to an external electrical device (e.g., printed circuit board (PCB)). The internal leads 126 electrically attach to an exposed surface of contact pads (leadframe attachment feature) 130 embedded in a surface of the substrate assembly 102 via first interconnects (e.g., solder paste, solder balls, etc.) 132 and via a protective layer 134 that protects the contact pads 130 from becoming oxidized. Although not illustrated, the contact pads 130 can be electrically connected to any one of the metal layers 118, 120 in the substrate assembly 102 thereby providing an electrical connection from the die 106 to the external device.

An active side 136 of the die (e.g., flip chip die) 106 attaches to a surface of the first metal layer 118 via second interconnects (e.g., solder balls) 138 and via the protective layer 134. Although, the die 106 illustrated in FIG. 1 is a flip chip die that attaches to the leadframe via solder balls, the die can also be connected to the leadframe via wire bonding. Thus, the configuration of the electronic device 100 and the die 106 illustrated in FIG. 1 is for illustrative purposes only and is not intended to limit the scope of the invention. The mold compound 108 is formed such that the mold compound 108 encapsulates the substrate assembly 102, the die 106, and the internal leads 126.

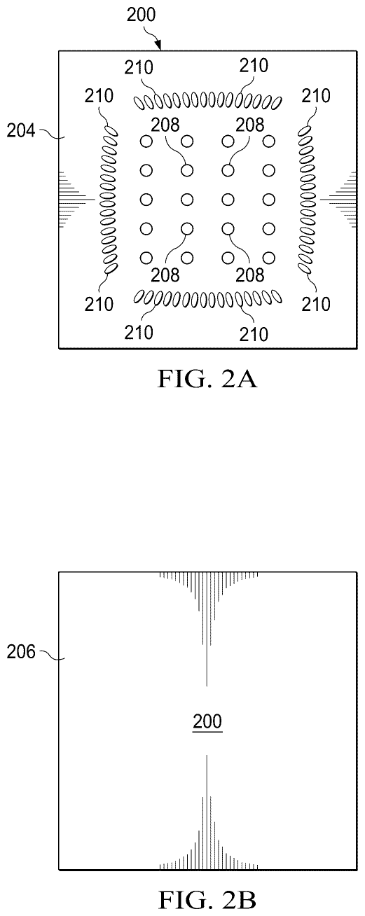

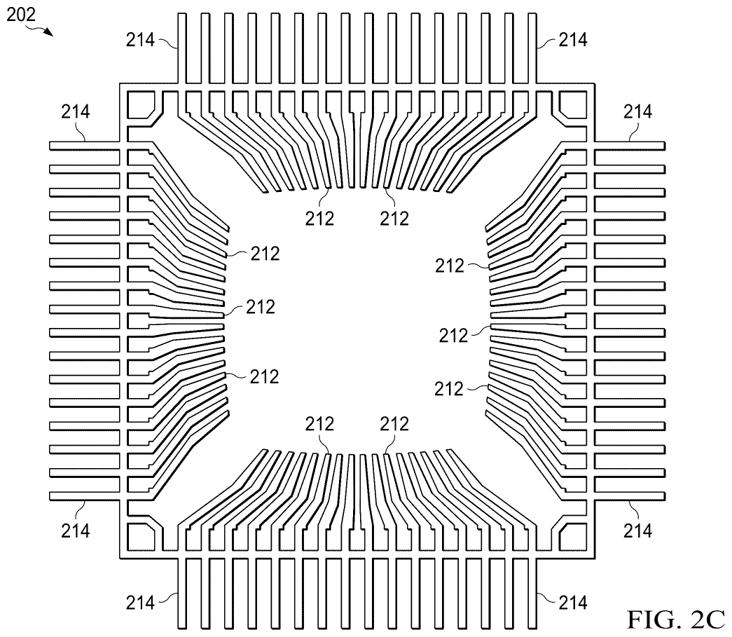

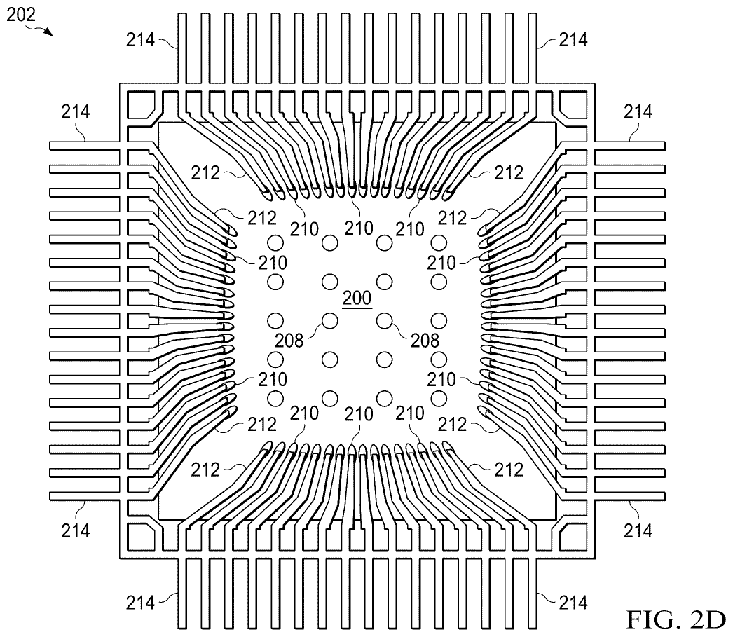

Referring to FIGS. 2A-2D, FIGS. 2A and 2B are top and bottom views respectively of an example substrate 200, FIG. 2C is a bottom view of an example leadframe 202, and FIG. 2D is a transparent bottom view of the substrate 200 attached to the leadframe 202.

The substrate (e.g., Epoxy, Ajinomoto Build-up Film (ABF), or Bismaleimide Triazine (BT)) 200 has a first (top) surface 204 (FIG. 2A) and a second (bottom) surface 206 (FIG. 2B). As illustrated in FIG. 2A, metal portions 208 of a first metal layer of the substrate 200 and metal contact pads 210 are exposed on the first surface 204 of the substrate 200. As will be illustrated further below, bump bonds of a die attach to the metal portions 208 of the first metal layer of the substrate 200.

Referring to FIG. 2C, the leadframe 202 includes internal leads 212 and external leads 214. When the substrate 200 is attached to the leadframe 202 as illustrated in FIG. 2D, the exposed contact pads 210 attach to the internal leads 212 of the leadframe 202 to provide electrical connections between the substrate 200 and the leadframe 202 (the substrate 200 in FIG. 2D is transparent so that the connection between the exposed contact pads 210 of the substrate 200 and the internal leads 212 of the leadframe 202 is visible).

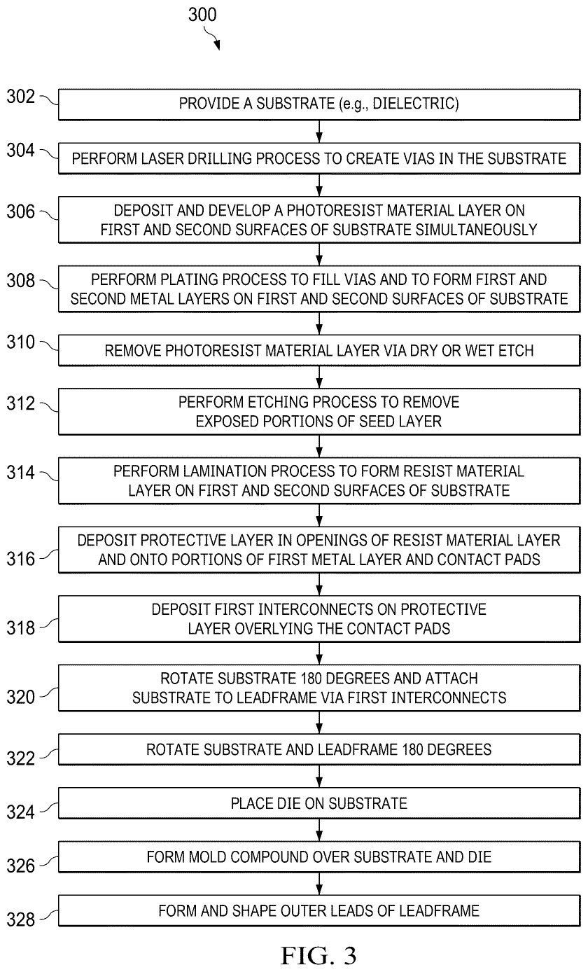

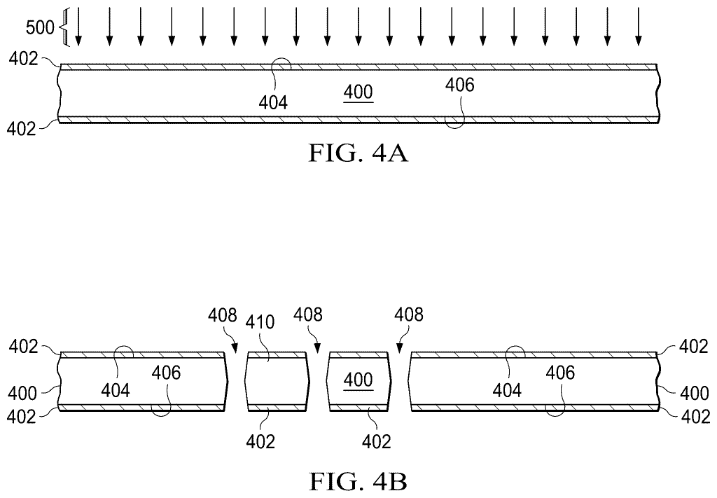

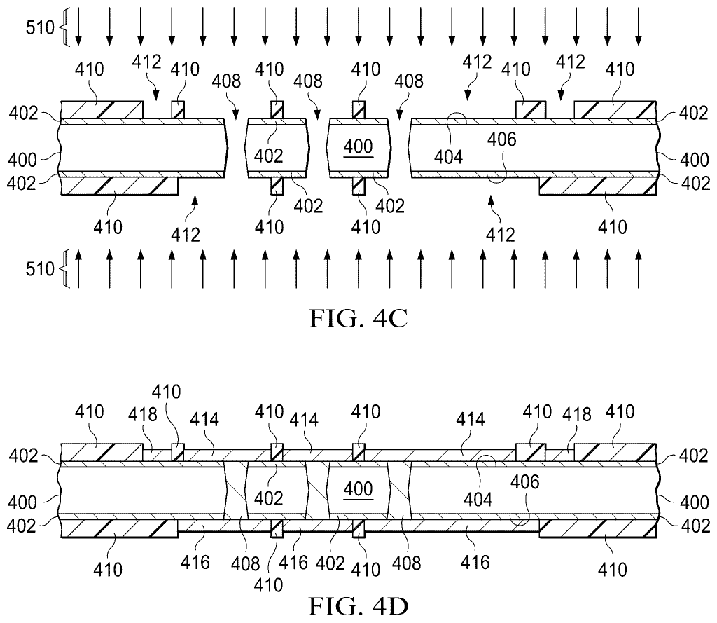

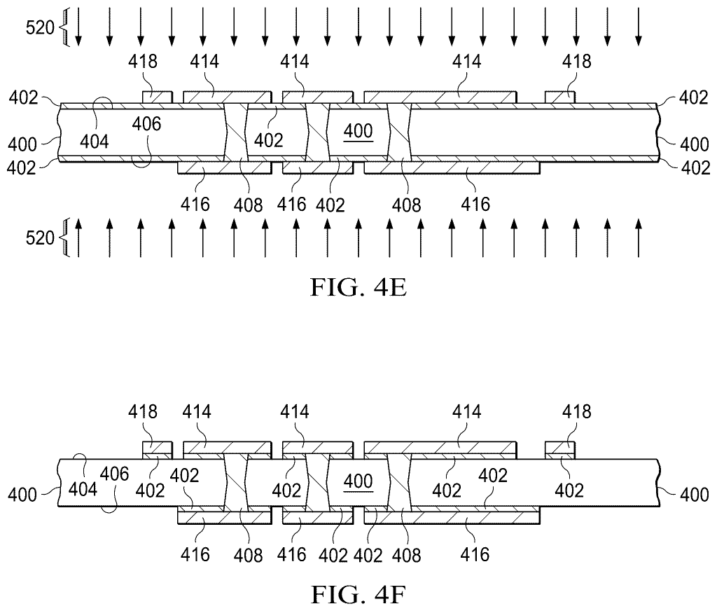

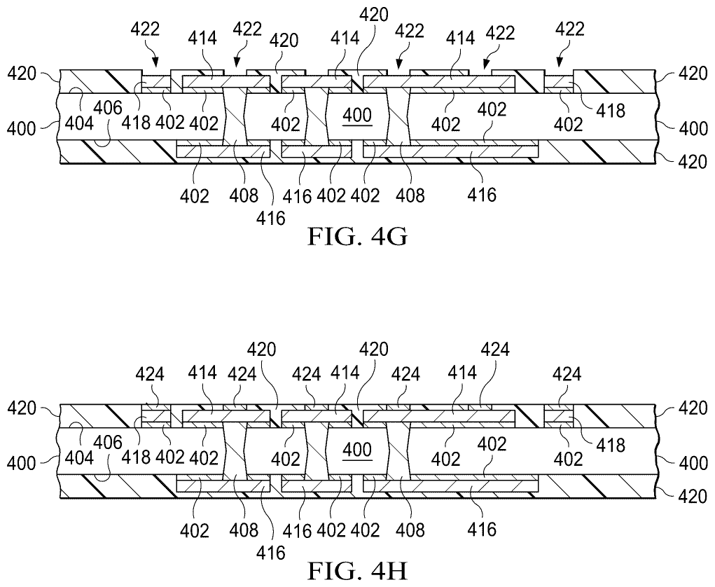

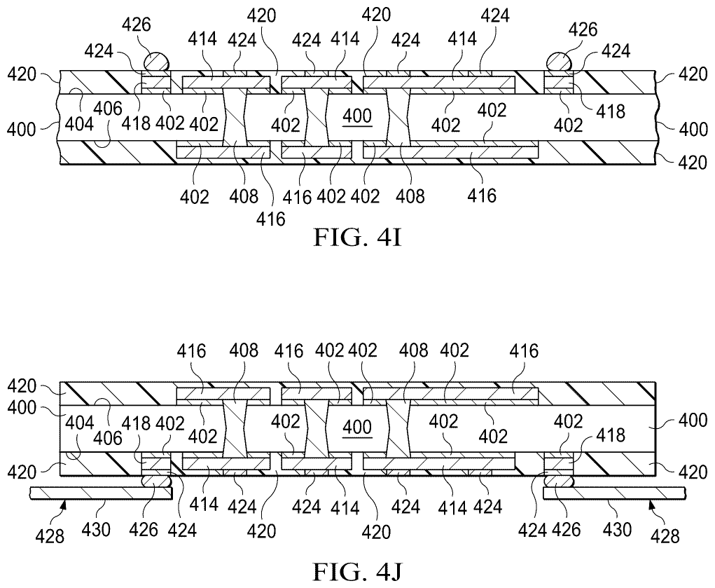

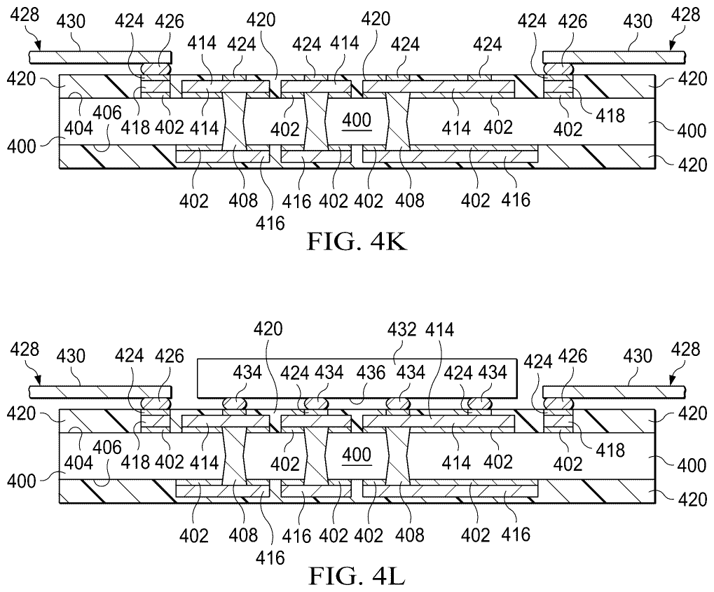

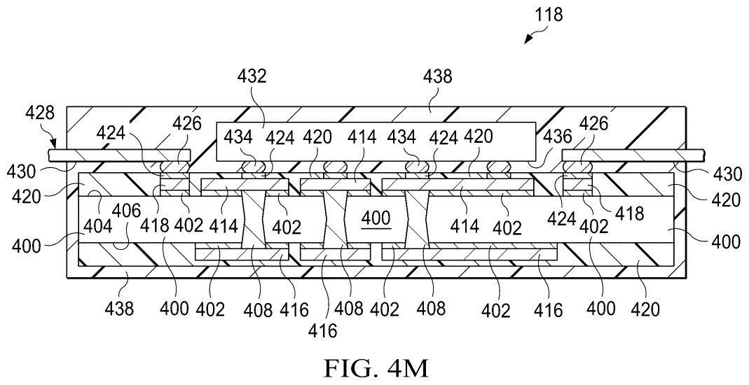

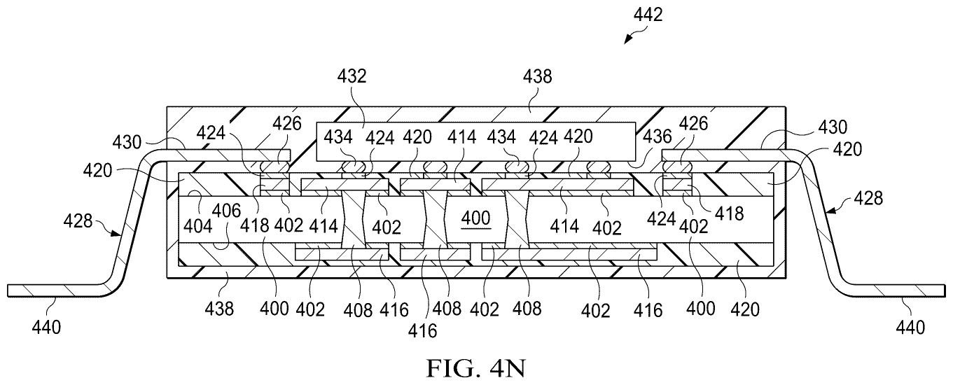

FIG. 3 is a block diagram flow chart explaining a fabrication process 300 and FIGS. 4A-4N illustrate the fabrication process associated with the formation of the electronic device 100 illustrated in FIG. 1. Though depicted sequentially as a matter of convenience, at least some of the actions shown can be performed in a different order and/or performed in parallel. Alternatively, some implementations may perform only some of the actions shown. Still further, although the example illustrated in FIGS. 3 and 4A-4N is an example method illustrating the example configuration of FIG. 1, other methods and configurations are possible. It is understood that although the method illustrated in FIGS. 3 and 4A-4N depicts the fabrication process of a single electronic device, the process applies to an array of electronic devices. Thus, after fabrication of the array of electronic devices the array is singulated to separate each electronic device 100 from the array.

Referring to FIG. 3 and to FIGS. 4A-4N, the fabrication process 300 of the electronic device 100 illustrated in FIG. 1 begins at 302 with a substrate 400 having a seed layer (e.g., copper) 402 on both a first surface 404 and a second surface 406 of the substrate 400. At 304, the configuration in FIG. 4A undergoes a laser drilling/etching process 500 to drill vias 408 in the substrate 400 resulting in the configuration of FIG. 4B. At 306, a photoresist material layer 410 overlies both the first and second surfaces 404, 406 simultaneously of the substrate 400 and is patterned and developed to expose openings 412 in the photoresist material layer 410 over the substrate 400, resulting in the configuration of FIG. 4C. The photoresist material layer 410 can have a thickness that varies in correspondence with the wavelength of radiation used to pattern the photoresist material layer 410. The photoresist material layer 410 may be formed over the substrate 400 via spin-coating or spin casting deposition techniques, selectively irradiated (e.g., via deep ultraviolet (DUV) irradiation) and developed to form the openings 412.

At 308, the configuration in FIG. 4C undergoes a plating (electroplating) process 510 resulting in the configuration of FIG. 4D. Specifically, simultaneously the vias 408 are filled with a conductive material (e.g., copper), a first metal layer (trace) (e.g., copper) 414 is plated on the seed layer 402 on the first surface 404 of the substrate 400, and a second metal layer 416 is plated on the seed layer 402 on the second surface 406 of the substrate 400. Furthermore, contact pads (leadframe attachment feature) 418 are plated on the seed layer 402 on the first surface 404 near a perimeter of the substrate 400. The configuration of the first and second metal layers 414, 416 can be comprised a single solid metal portion or can be comprised of multiple metal portions physically separated by a gap or gaps, as illustrated in FIG. 4D. Therefore, the example first and second metal layers 414, 416 illustrated in FIG. 4D are for illustrative purposes only and are not intended to limit the scope of the invention.

At 310, the photoresist material layer 410 is removed via a dry or wet etch process resulting in the configuration of FIG. 4E. At 312, the configuration in FIG. 4E undergoes an etching process 520 to remove exposed portions of the seed layer 402 from both the first and second surfaces 404, 406 of the substrate 400 resulting in the configuration of FIG. 4F. At 314, the configuration of FIG. 4F undergoes a lamination process to laminate the first and second surfaces 404, 406 of the substrate 400 with a resist material layer 420 resulting in the configuration of FIG. 4G. The resist material layer 420 includes openings 422 over portions of the first metal layer 414 and over the contact pads 418 as illustrated in FIG. 4G.

At 316, a protective layer (e.g., OSP, NiCu) 424 is deposited in the openings 422 of the resist material layer 420 and onto the portions of the first layer 414 and on the contact pads 415, resulting in the configuration of FIG. 4H. The protective layer 424 protects the first metal layer 414 and the contact pads 418 from becoming oxidized.

At 318, the configuration in FIG. 4H undergoes a screen printing process to deposit first interconnects (e.g., solder paste, solder balls, etc.) 426 on the protective layer 424 overlying the contact pads 418 resulting in the configuration of FIG. 4I.

At 320, the substrate 400 is rotated 1800 and is attached to a leadframe 428 via the first interconnects 426 resulting in the configuration of FIG. 4J. Specifically, the contact pads 418 of the substrate 400 attach to internal leads 430 of the leadframe 428 via the first interconnects 426. At 322, the configuration of FIG. 4J is once again rotated 180° resulting in the configuration of FIG. 4K. At 324, a die 432, which includes second interconnects (e.g., solder balls) 434 attached to an active side 436 of the die 432, is placed the first metal layer 414 such that the second interconnects 434 attach to the first metal layer 414 via the protective layer 424 resulting in the configuration of FIG. 4L. At 326, a mold compound 438 is formed over and encapsulates the substrate 400, the die 432, and the internal leads 430 resulting in the configuration of FIG. 4M. At 328, external leads 440 of the leadframe 428 are formed and shaped to extend below the mold compound 438 for mounting on an external electrical device (e.g., PCB) resulting in the electronic device 442 illustrated in FIG. 4N.

It is to be understood that the example resulting electronic device 442 illustrated in FIG. 4N is just one example of a semiconductor package that can be fabricated with the leaded substrate configuration. More specifically, the leaded substrate configuration enables the use of a single sized leadframe (e.g., n×n) that can be used with different sized substrates to create multiple semiconductor packages based on the application of the semiconductor. Thus, the example electronic device and process disclose herein are for illustrative purposes only and are not intended to limit the scope of the invention.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a leadframe;
a substrate assembly having a leadframe attachment feature configured to attach to the leadframe;
at least one metal layer embedded in the substrate assembly, the at least one metal layer having an exposed surface;
a die attached to the exposed surface of the at least one metal layer; and
a mold compound encapsulating the substrate assembly and the die.

2. The electronic device of claim 1, wherein the substrate assembly includes a substrate having a first surface and a second surface, wherein the at least one metal layer is a first metal layer disposed on the first surface of the substrate, the electronic device further including a second metal layer disposed on the second surface of the substrate.

3. The electronic device of claim 2, wherein the substrate assembly further includes a resist material layer disposed on the first and second surfaces of the substrate and overlying the first and second metal layers, the resist material layer overlying the first metal layer including openings to expose portions of the first metal layer.

4. The electronic device of claim 3, wherein the leadframe attachment feature are contact pads disposed on the first surface of the substrate, the contact pads having an exposed surface that attaches to the leadframe.

5. The electronic device of claim 4, wherein the leadframe includes internal leads encapsulated in the mold compound, the exposed surface of the contact pads being attached to the internal leads via first interconnects.

6. The electronic device of claim 5 further comprising a via layer disposed between the first metal layer and the second metal layer, the via layer electrically connecting the first and second metal layers.

7. The electronic device of claim 6, wherein the die includes an active side, the active side of the die being attached to the exposed portions of the first metal layer via second interconnects.

8. The electronic device of claim 7, wherein the leadframe includes external leads disposed outside the mold compound, the external leads being configured to attach to an electrical device.

9. An electronic device comprising:
a substrate having a first surface and a second surface;
a first metal layer deposited on the first surface of the substrate;
a second metal layer deposited on the second surface of the substrate;
a resist material layer disposed on the first and second surfaces of the substrate and over the first and second metal layers, the resist material having openings to expose portions of the first metal layer;
a leadframe attached to a leadframe attachment feature disposed on the substrate;
a die attached to the first metal layer; and
a mold compound formed over the substrate and the die.

10. The electronic device of claim 9, wherein the leadframe attachment feature are contact pads disposed on the first surface of the substrate, the contact pads having an exposed surface, the leadframe being attached to the exposed surface of the contact pads.

11. The electronic device of claim 10, wherein the leadframe includes internal leads encapsulated in the mold compound, the internal leads being attached to the exposed surface of the contact pads via first interconnects.

12. The electronic device of claim 11, wherein the leadframe includes external leads disposed outside the mold compound, the external leads being configured to attach to an electrical device.

13. The electronic device of claim 12, wherein the die includes an active side, the active side of the die being attached to the exposed portions of the first metal layer via second interconnects.

14. The electronic device of claim 13, wherein the first interconnects and the second interconnects are comprised at least one of solder paste and solder balls.

15. The electronic device of claim 9 further comprising a via layer disposed between the first metal layer and the second metal layer.

16. A method comprising:
forming at least one metal layer on at least one surface of a substrate;
forming contact pads on the at least one surface of the substrate;
attaching the contact pads of the substrate to a leadframe via first interconnects;
attaching a die to the at least one metal layer via second interconnects; and
forming a mold compound over the substrate and the die.

17. The method of claim 16, wherein prior to forming at least one metal layer on at least one surface of a substrate, the method comprising performing a laser drilling process to form vias in the substrate.

18. The method of claim 17, wherein prior to attaching the contact pads of the substrate to a leadframe via first interconnects, the method comprising performing a lamination process to form a resist material layer on the at least one surface of the substrate and over the at least one metal layer, the resist material layer having openings to expose portions of the at least one metal layer and the contact pads.

19. The method of claim 18 further comprising depositing a protective layer in the openings of the resist material layer and onto the exposed portions of the at least one metal layer and the contact pads.

20. The method of claim 19, wherein the at least one metal layer is a first metal layer and the at least one surface of the substrate is a first surface, the method further comprising forming a second metal layer on a second surface of the substrate and forming the resist material layer on the second surface of the substrate and over the second metal layer.

21. The method of claim 17, wherein forming the at least one metal layer on the at least one surface of the substrate comprises performing a plating process to deposit metal on a first surface of the substrate to form a first metal layer, the first metal layer having an exposed surface.

22. The method of claim 21 further comprising forming a second metal layer via the plating process on a second surface opposite that of the first surface of the substrate, the vias electrically connecting the first and second metal layers.

23. The method of claim 22, wherein forming contact pads on the at least one surface of the substrate comprises performing the plating process to deposit metal on the first surface of the substrate, the contact pads having an exposed surface.
